(19) United States
(12) Patent Application Publication
(10) Pub. No.: US 2026/0136895 A1
(43) Pub. Date: May 14, 2026

(54) SEMICONDUCTOR STRUCTURE

(71) Applicant: Taiwan Semiconductor Manufacturing Company, Ltd., Hsinchu (TW)

(72) Inventors: Ching-Wen HSIAO, Hsinchu City (TW); Cheng-Nan LIN, Hsinchu city (TW); Ching-Ho CHENG, Hsinchu City (TW); Wei-Ren HUANG, Hsinchu City (TW); Yu-Tse SU, Chiayi City (TW)

(21) Appl. No.: 18/946,008

(22) Filed: Nov. 13, 2024

(51) Int. Cl. H01L 21/66; H01L 23/498

(52) U.S. Cl. CPC H10P 74/273; H10W 70/65; H10W 70/685

(57) ABSTRACT

A semiconductor structure is provided. The semiconductor structure includes a device layer on a substrate, and an interconnect structure over the device layer. The interconnect structure includes a redistribution layer. The substrate is defined as a die region and a scribe line region. The redistribution layer includes a first probe pad and a first first-type monitor structure within the scribe line region. The first first-type monitor structure includes a plurality of first metal patterns. The first probe pad is wider than the first metal patterns. The first probe pad is longer than the first metal patterns.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or insulating layers, conductive layers, and semiconductive layers of material over a semiconductor substrate, and patterning the various material layers using lithography to form circuit components and elements thereon. Dozens or hundreds of integrated circuits are manufactured on a single semiconductor structure. The individual dies are typically singulated by sawing the integrated circuits along a scribe line. The individual dies are then packaged separately, in multi-die modules, or in other types of packaging, for example.

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (PoP) devices and so on. With the shrink in the size of the packages, the challenges of fabricating the packages become more difficult.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A illustrates a top view of a semiconductor structure with die regions and a scribe line region, in accordance with some embodiments of the present disclosure.

FIG. 1B is an enlarged view of area R shown in FIG. 1A to illustrate probe pads and monitor structures within the scribe line region, in accordance with some embodiments of the present disclosure.

FIG. 1C illustrates a top view of a probe pad, in accordance with some embodiments of the present disclosure.

FIG. 1D illustrates a top view of a first-type monitor structure, in accordance with some embodiments of the present disclosure.

FIG. 1E illustrates a top view of a second-type monitor structure, in accordance with some embodiments of the present disclosure.

FIG. 2 is a perspective view of a fin structure formed on a semiconductor substrate, in accordance with some embodiments of the disclosure.

FIGS. 3A and 3B are cross-sectional views illustrating the formation of a semiconductor substrate at various intermediate stages, in accordance with some embodiments of the disclosure.

FIGS. 4A and 4B are cross-sectional views illustrating the singulation of dies at various intermediate stages, in accordance with some embodiments of the disclosure.

FIG. 4C illustrates a top view of a semiconductor die with a die region and a scribe line region, in accordance with some embodiments of the present disclosure.

FIG. 5 is a cross-sectional view of a package structure including a semiconductor die shown in FIGS. 4B and 4C, in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100%. Furthermore, terms such as “substantially parallel” or “substantially perpendicular” are to be interpreted as not to exclude insignificant deviation from the specified arrangement and may include for example deviations of up to 10°. The word “substantially” does not exclude “completely” e.g. a composition which is “substantially free” from Y may be completely free from Y.

Terms such as “about” in conjunction with a specific distance or size are to be interpreted so as not to exclude insignificant deviation from the specified distance or size and may include for example deviations of up to 10%. The term “about” in relation to a numerical value x may mean x ±5 or 10%.

Some embodiments of the disclosure are described. Additional operations can be provided before, during, and/or after the stages described in these embodiments. Some of the stages that are described can be replaced or eliminated for different embodiments. Additional features can be added to the structures of the embodiments. Some of the features described below can be replaced or eliminated for different embodiments. Although some embodiments are discussed with operations performed in a particular order, these operations may be performed in another logical order.

Embodiments of the disclosure may relate to 3D packaging or 3D-IC devices. Other features and processes may also be included. For example, testing structures may be included to aid in the verification testing of the 3D packaging or 3D-IC devices. The testing structures may include, for example, test pads formed in a redistribution layer or on a substrate that allows the testing of the 3D packaging or 3D-IC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments of a semiconductor substrate are provided. The semiconductor structure includes a test probe pad and a monitor structure within a scribe line region. The monitor structure includes a plurality of small metal patterns arranged in an array, and thus has a lower areal density of patterns than that of the test probe pad. As a result, the monitor structure may suffer heavier laser grooving during a laser-grooving process. It may be determined that the dimension of the entire groove meets the specification by inspecting the groove at the position where the monitor structure is disposed. Therefore, the manufacturing yield of the semiconductor structure may be improved.

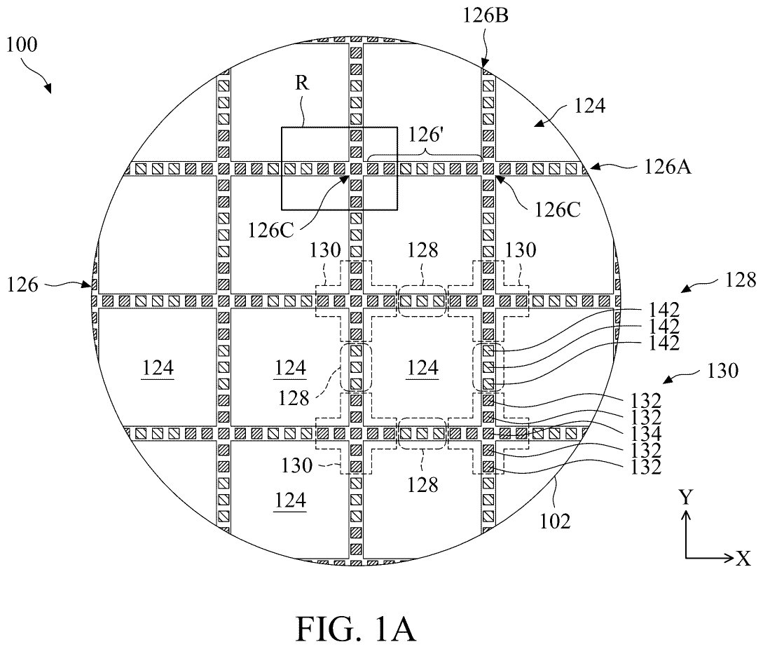

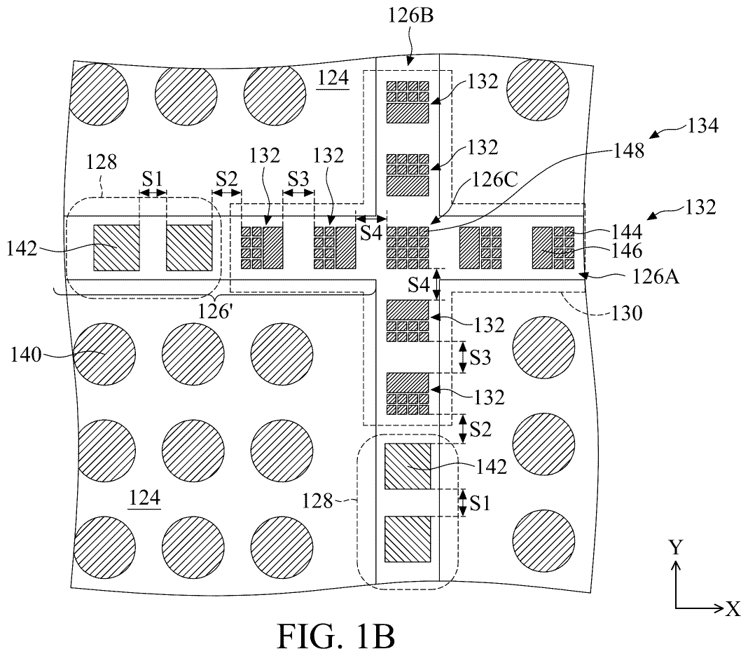

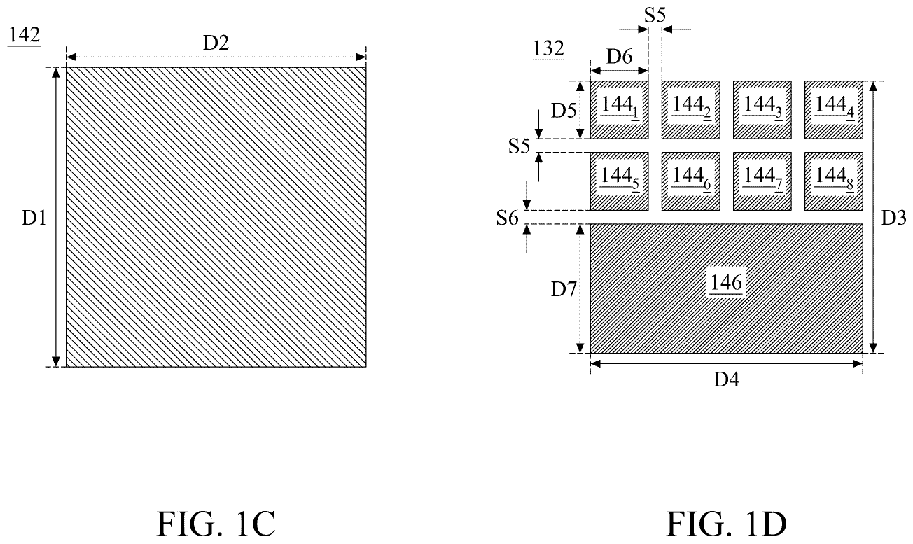

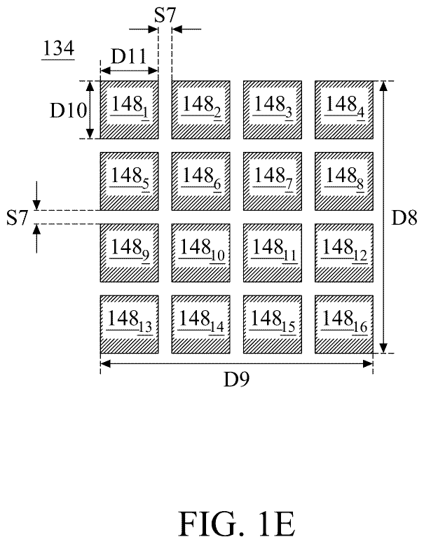

FIG. 1A illustrates a top view of a semiconductor structure 100 with die regions 124 and a scribe line region 126, in accordance with some embodiments of the present disclosure. The semiconductor structure 100 may be a semiconductor wafer, in accordance with some embodiments. The semiconductor structure 100 includes a semiconductor substrate 102, a device layer on the semiconductor substrate 102 and an interconnect structure on the device layer, in accordance with some embodiments. The semiconductor substrate 102 (or the semiconductor structure 100) may be defined as a plurality of die regions 124 and a scribe line region 126 surrounding the die regions 124, in accordance with some embodiments. The die regions 124 are separate from each other by the scribe line region 126, in accordance with some embodiments.

Semiconductor dies in the die regions 124 may be singulated by cutting the semiconductor substrate 100 along the scribe line regions 126 (e.g., using a laser-grooving process and a mechanical dicing process) to obtain individual dies, in accordance with some embodiments. Each of the semiconductor dies includes integrated circuits, which are electrically coupled to each other through the interconnect structure, in accordance with some embodiments. In some embodiments, in each die region 124, a seal ring structure (not shown) is formed to surround the corresponding semiconductor die.

The scribe line region 126 has grid-like distribution, in accordance with some embodiments. The scribe line region 126 includes a plurality of first streets 126A extending in the X direction and a plurality of second streets 126B extending in the Y direction, in accordance with some embodiments. The first streets 126A intersect the second streets 126B at crossroads 126C, in accordance with some embodiments. Each of the streets 126A and 126B includes several segments 126′ between the crossroads 126C, in accordance with some embodiments.

The scribe line region 126 is defined as a plurality of testline regions 128 and a plurality of or monitor cross regions 130, in accordance with some embodiments. The testline regions 128 are located on the center portions of the segments 126′ of the streets 126A and 126B, in accordance with some embodiments. A plurality of probe pads 142 are disposed within each testline region 128, in accordance with some embodiments. Although three probe pads 142 are shown as within each testline region 128, in some embodiments, two or more than three (e.g., 4-10) probe pads 142 may be disposed within each testline region 128.

The monitor cross regions 130 are correspondingly located on the crossroads 126C, and each of the monitor cross regions 130 includes four extending portions on the end portions of the segments 126′ of the streets 126A and 126B, in accordance with some embodiments. A plurality of first-type monitor structures 132 and a second-type monitor structure 134 are disposed within each monitor cross region 130, in accordance with some embodiments. In specific, two first-type monitor structures 132 are disposed within each extending portion of the monitor cross regions 130 (i.e., on the end portion of the segments 126′), and one second-type monitor structure 134 is disposed on the crossroad 126C, in accordance with some embodiments. In some other embodiments, one or more than two (e.g., 3-5) first-type monitor structures 132 may be disposed within each extending portion of the monitor cross region 130.

The probe pads 142 and the monitor structures 132 and 134 are metal patterns of a redistribution layer in the interconnect structure, in accordance with some embodiments. Although not shown in FIG. 1A, the redistribution layer further includes bonding pads distributed within the die regions 124.

The probe pads 142 in the testline regions 128 are electrically coupled with the integrated circuits in the device layer through the conductive features in the interconnect structure, in accordance with some embodiments. In a wafer acceptance test (WAT), the probe pads 142 in the testline regions 128 are electrically connected to an external circuit or probes of a probe card, in accordance with some embodiments. The probe pads 142 are selected to test the electrical properties of the wafer, such as gate oxide thickness, leakage current, contact resistance, sheet resistance, breakdown voltage, threshold voltage, saturation current, and/or a combination thereof. The wafer acceptance test is performed to determine the acceptance rate of the semiconductor structure 100, in accordance with some embodiments.

For illustration simplicity, each of the monitor structures 132 and 134 are shown as a single metal pattern. However, each of the monitor structures 132 and 134 includes a plurality of smaller metal patterns, which may be discussed in detail later. The monitor structure 132 and 134 in the monitor cross regions 130 have a lower areal density of patterns than the probe pads 142 in the testline regions 128, in accordance with some embodiments.

In a laser-grooving process, a laser beam is applied to the semiconductor structure 100 along the scribed line region 126, thereby forming a groove, in accordance with some embodiments. The monitor structure 132 and 134 with lower areal density of patterns may suffer heavier laser grooving during the laser-grooving process, and thus provide a worse condition, in accordance with some embodiments. A groove monitor process is performed to determine if the entire groove meets the specification of dimension by monitoring the dimension (e.g., depth or width) of the groove at the position of the monitor cross regions 130.

FIG. 1B is an enlarged view of area R shown in FIG. 1A to illustrate the bonding pad 140 within the die regions 124, the probe pads 142 within the testline regions 128 and the monitor structures 132 and 134 within the monitor cross region 130, in accordance with some embodiments of the present disclosure. FIGS. 1C, 1D and 1E respectively illustrate a top view of the probe pad 142, a top view of the first-type monitor structure 132 and a top view of the second-type monitor structure 134.

Each of the probe pads 142 within the testline regions 128 is a single metal pattern with a rectangular shape, and has a dimension D1 in the Y direction (e.g., width or length) and a dimension D2 (e.g., width or length) in the X direction, as shown in FIGS. 1B and 1C, in accordance with some embodiments. In some embodiments, the dimension D1 is in a range from about 1 μm to about 100 μm. In some embodiments, the dimension D2 is in a range from about 1 μm to about 100 μm. In some embodiments, the spacing S1 between adjacent two probe pads 142 is in a range from about 1 μm to about 100 μm.

Each of the first-type monitor structure 132 within the monitor cross region 130 includes a plurality of small metal patterns (or first-type metal patterns) 144₁₋₈ and one large metal pattern (or a second-type metal pattern) 146, as shown in FIGS. 1B and 1D, in accordance with some embodiments. For illustration simplicity, features of the first-type monitor structure 132 may be described below using the first-type monitor structure 132 in the second street 126B, but these features can be suitable for the first-type monitor structure 132 in the first street 126A. In some embodiments, the first-type monitor structures 132 have rectangular shapes. The large metal pattern 146 is disposed closer to the crossroad 126C than the small metal patterns 144₁₋₈, in accordance with some embodiments.

The first-type monitor structure 132 has a dimension D3 in the Y direction (e.g., width or length) and a dimension D4 (e.g., width or length) in the X direction, in accordance with some embodiments. In some embodiments, the dimension D3 is in a range from about 1 μm to about 100 μm. In some embodiments, the dimension D4 is in a range from about 1 μm to about 100 μm. In some embodiments, the dimension D3 of the first-type monitor structure 132 is substantially equal to the dimension D1 of the probe pad 142, and the dimension D4 of the first-type monitor structure 132 is substantially equal to the dimension D2 of the probe pad 142.

In some embodiments, the spacing S2 between the probe pad 142 and the first-type monitor structure 132 is in a range from about 1 μm to about 100 μm. In some embodiments, the spacing S3 between adjacent two first-type monitor structure 132 is in a range from about 1 μm to about 100 μm. In some embodiments, the spacing S1, the spacing S2 and the spacing S3 are substantially equal.

The small metal patterns 144 of the first-type monitor structure 132 are arranged in an array, e.g., a 2×4 array, in accordance with some embodiments. That is, the small metal patterns 144₁₋₄ are arranged sequentially in the X direction in the first row; the small metal patterns 144₅₋₈ are arranged sequentially in the X direction in the second row; the small metal patterns 144₁ and 144₅ are aligned in the Y direction in the first column; the small metal patterns 144₂ and 144₆ are aligned in the Y direction in the second column; the small metal patterns 144₃ and 144₇ are aligned in the Y direction in the third column; and the small metal patterns 144₄ and 144₈ are aligned in the Y direction in the fourth column, in accordance with some embodiments. In some other embodiments, the small metal patterns 144 may be arranged in 2×2 array, a 2×3 array, a 3×4 array, a 4×4 array, etc.

In the illustrated embodiments, the left sidewalls of the small metal patterns 144₁ and 144₅ are substantially aligned with the left sidewall of the large metal pattern 146, and the right sidewalls of the small metal patterns 144₄ and 144₈ are substantially aligned with the right sidewall of the large metal pattern 146.

The small metal pattern 144 is a single metal pattern with a rectangular shape, and has a dimension D5 in the Y direction (e.g., width or length) and a dimension D6 (e.g., width or length) in the X direction, in accordance with some embodiments. In some embodiments, the dimension D5 is in a range from about 1 μm to about 25 μm. In some embodiments, the dimension D6 is in a range from about 1 μm to about 25 μm. In some embodiments, the spacing S5 between adjacent two small metal patterns 144 is in a range from about 1 μm to about 10 μm.

The large metal pattern 146 is a single metal pattern with a rectangular shape, and has a dimension D7 in the Y direction (e.g., width or length) and a dimension D4 (e.g., width or length) in the X direction, in accordance with some embodiments. In some embodiments, the dimension D7 is less than the dimension D4, and is in a range from about 1 μm to about 100 μm, or about 25 μm to about 100 μm. In some embodiments, the dimension D4 is in a range from about 1 μm to about 100 μm, or about 25 μm to about 100 μm.

The large metal pattern 146 is greater than the small metal pattern 144 in both width and length, in accordance with some embodiments. That is, in some embodiments, the dimensions D7 of the large metal pattern 146 is greater than the dimension D5 of the small metal pattern 144, and the dimensions D4 is greater than the dimension D6 of the small metal pattern 144. For example, the ratio (D7/D5) of the dimension D7 to the dimensions D5 is greater than about 1 and less than about 15, and the ratio (D4/D6) of the dimension D4 to the dimensions D6 is greater than about 1 and less than about to about 30.

In some embodiments, the spacing S6 between the small metal patterns 144 and the large metal pattern 146 is in a range from about 1 μm to about 10 μm. In some embodiments, the spacing S5 is substantially equal to the spacing S6. In some embodiments, the spacings S5 and S6 are less than the spacings S1, S2 and S3. For example, the ratio (S3/S5) of the spacing S3 to the spacing S5 is in a range from about 1 to about 10. In some embodiments, the spacings S5 and S6 are less than the dimensions D5 and D6.

In some embodiments, the dimension D1 of the probe pad 142 is greater than the dimension D7 of the large metal pattern 146. For example, the ratio (D1/D7) of the dimension D1 to the dimension D7 is greater than about 1 and less than about 3. In some embodiments, the dimension D2 of the probe pad 142 is substantially equal to the dimension D4 of the large metal pattern 146. The large metal pattern 146 may be also referred to as dummy probe pad, and is not used a probe pad for the wafer acceptance test.

An areal density of patterns in the first-type monitor structure 132, defined as the ratio ((D5×D6×8+D7×D4)/(D3×D4)) of the sum of the areas of the eight small metal patterns 144 and the area of the large metal pattern 146 to the area of the first-type monitor structure 132 is greater than 0.70 and less than 0.90. In some embodiments, the areal density of patterns in the first-type monitor structure 132 is less than the areal density (i.e., 100%) of pattern in the probe pad 142.

Because the metal patterns can absorb and/or reflect the laser beam in the laser-grooving process, the greater the areal density of metal patterns, the lower the machinability, and vice versa. As a result, the first-type monitor structure 132 with a relatively low areal density of patterns may suffer heavier laser grooving, and thus may provide a worse condition for the groove monitor process.

Once the dimension of the groove at the position where the first-type monitor structures 132 are disposed meets the specification, it may be determined that the dimension of the groove at other locations in the scribe line region 126 also meets the specification. Therefore, the first-type monitor structure 132 may provide specific target patterns for in-line monitor to find out defects caused by poor process deviation/margin, such as laser power decline, tool difference, etc. In addition, because the first-type monitor structure 132 includes large metal pattern 146, the areal density of patterns in the first-type monitor structure 132 may be not too low to cause excessive laser grooving, in accordance with some embodiments.

Each of the second-type monitor structure 134 within the monitor cross region 130 includes a plurality of small metal patterns (or third-type metal patterns) 148₁₋₁₆, as shown in FIGS. 1B and 1E, in accordance with some embodiments. In some embodiments, the second-type monitor structure 134 has a rectangular shape. The second-type monitor structure 134 has a dimension D8 in the Y direction (e.g., width or length) and a dimension D9 (e.g., width or length) in the X direction, in accordance with some embodiments. In some embodiments, the dimension D8 is in a range from about 1 μm to about 100 μm. In some embodiments, the dimension D9 is in a range from about 1 μm to about 100 μm.

In some embodiments, the dimension D8 of the second-type monitor structure 134 is substantially equal to the dimension D3 of the first-type monitor structure 132, and the dimension D9 of the second-type monitor structure 134 is substantially equal to the dimension D4 of the first-type monitor structure 132. In some embodiments, the spacing S4 between the second-type monitor structure 134 and the first-type monitor structure 132 is in a range from about 1 μm to about 100 μm. In some embodiments, the spacing S4 is substantially equal to the spacing S3.

The small metal patterns 148 of the second-type monitor structure 134 are arranged in an array, e.g., a 4×4 array, in accordance with some embodiments. That is, the small metal patterns 148₁₋₄ are arranged sequentially in the X direction in the first row; the small metal patterns 144₅₋₈ are arranged sequentially in the X direction in the second row; the small metal patterns 148₉₋₁₂ are arranged sequentially in the X direction in the third row; and the small metal patterns 148₁₃₋₁₆ are arranged sequentially in the X direction in the fourth row. The small metal patterns 148₁, 148₅, 148₉ and 148₁₃ are aligned in the Y direction in the first column; the small metal patterns 148₂, 148₆, 148₁₀ and 148₁₄ are aligned in the Y direction in the second column; the small metal patterns 148₃, 148₇, 148₁₁ and 148₁₅ are aligned in the Y direction in the third column; and the small metal patterns 148₄, 148₈, 148₁₂ and 148₁₆ are aligned in the Y direction in the fourth column, in accordance with some embodiments. In some other embodiments, the small metal patterns 148 may be arranged in 2×2 array, a 3×3 array, a 5×5 array, a 6×6 array, etc.

The small metal patterns 148 is a single metal pattern with a rectangular shape, and has a dimension D10 in the Y direction (e.g., width or length) and a dimension D11 (e.g., width or length) in the X direction, in accordance with some embodiments. In some embodiments, the dimension D10 is in a range from about 1 μm to about 25 μm. In some embodiments, the dimension D11 is in a range from about 1 μm to about 25 μm. In some embodiments, the dimensions of the small metal patterns 148 are substantially equal to the dimensions of the small metal patterns 144, i.e., D5=D10 and D6=D11.

In some embodiments, the spacing S7 between the adjacent small metal patterns 148 is in a range from about 1 μm to about 10 μm. In some embodiments, the spacing S7 is substantially equal to spacing S5 and S6. In some embodiments, the spacing S7 is less than the dimension D9 and D10.

An areal density of patterns in the second-type monitor structure 134, defined as the ratio (i.e., (D10×D11×16)/(D8×D9)) of the sum of the areas of the small metal patterns 148 to the area of the second-type monitor structure 134 is greater than 0.5 and less than 0.9. In some embodiments, the areal density of patterns in the second-type monitor structure 134 is less than the areal density of patterns in the first-type monitor structure 132.

The laser-grooving process generally results in recast and debris due to the laser interaction with the interconnect structure and the semiconductor substrate. The severe recast and debris may cause the stress, which may result in the delamination issue of the dielectric layer (especially extremely low-k dielectric material) of the interconnect structure in the following reliability testing, thereby decreasing the yield. Because the crossroads 126C of the scribe line region 126 are been laser-grooved twice, the second-type monitor structure 134 with a lower areal density of patterns than that of the first-type monitor structure 132 may prevent the laser grooving at the crossroads 126C from being too heavy and causing the delamination issue, and at the same time prevent the laser groove from being too light to meet the dimension specification.

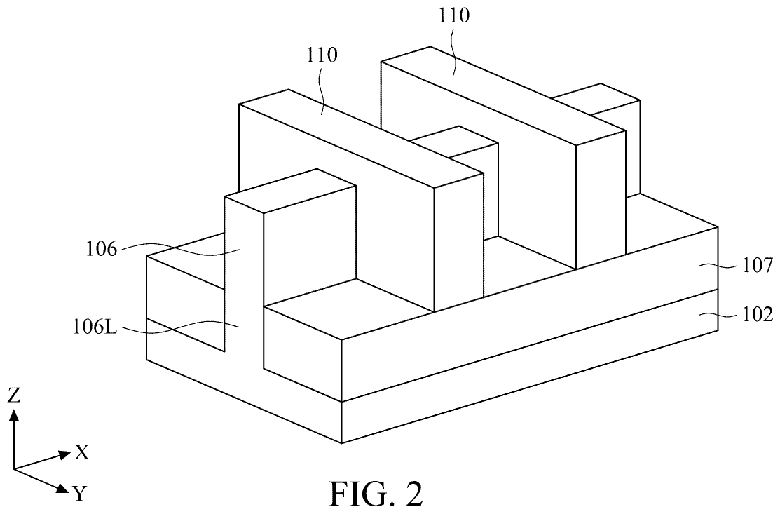

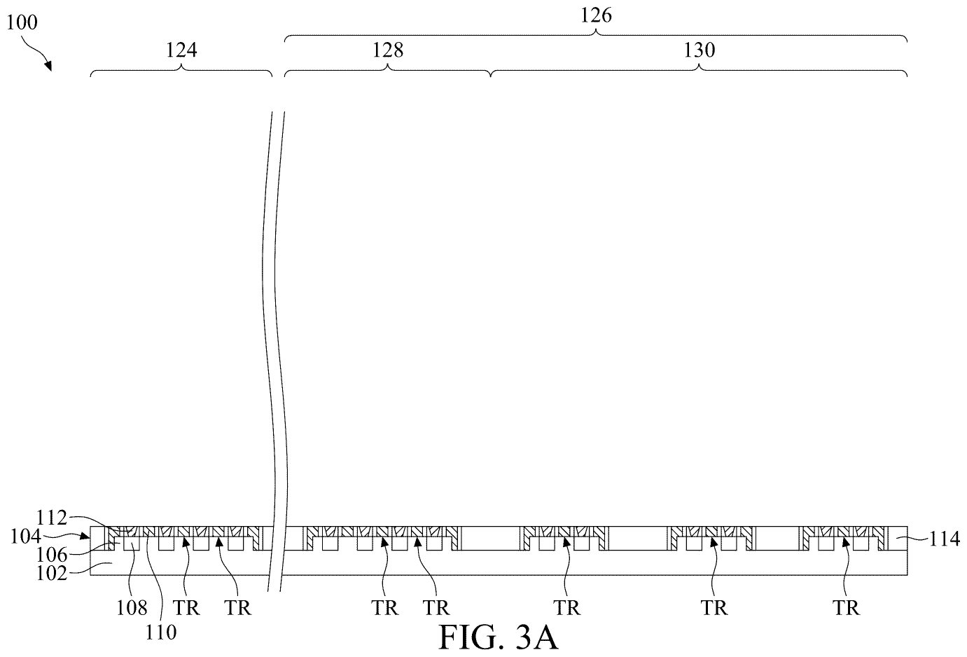

FIG. 2 is a perspective view of a fin structure 106 formed on a semiconductor substrate 102, in accordance with some embodiments of the disclosure. A fin structure 106 is formed over the semiconductor substrate 102, in accordance with some embodiments. The fin structure 106 is the active region of the semiconductor structure 100, in accordance with some embodiments. For a better understanding of the semiconductor structure, an X-Y-Z coordinate reference is provided. The X-axis and Y-axis are generally orientated along the lateral directions that are parallel to the main surface of the semiconductor structure 100. The Y-axis is transverse (e.g., substantially perpendicular) to the X-axis. The Z-axis is generally oriented along the vertical direction that is perpendicular to the main surface of a semiconductor structure 100 (or the X-Y plane).

The fin structure 106 extends in the X direction, in accordance with some embodiments. The current of the resulting semiconductor devices (i.e., FinFETs) flows in the X direction through the channel. The fin structure 106 is defined as several channel regions and source/drain regions, where the channel regions and the source/drain regions are alternately arranged, in accordance with some embodiments. An isolation structure 107 is formed over the semiconductor substrate 102 and surrounds the lower portion 106L of the fin structure 106, in accordance with some embodiments. Metal gates 110 are formed with longitudinal axes parallel to the Y direction and extending across or surrounding the channel regions of the fin structure 106, in accordance with some embodiments. The source/drain regions of the fin structure 106 are exposed from the metal gates 110, in accordance with some embodiments.

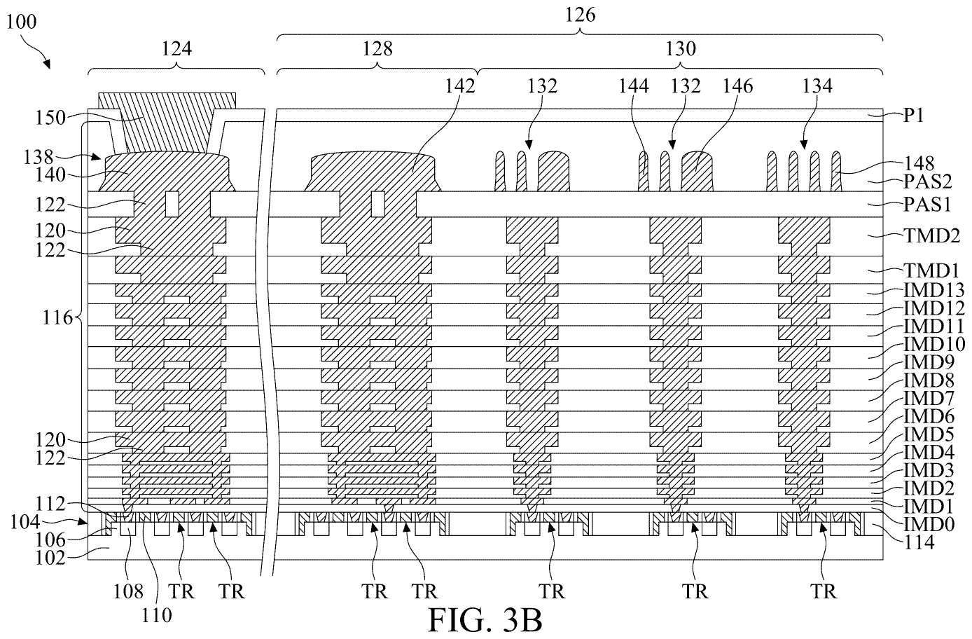

FIGS. 3A and 3B are cross-sectional views illustrating the formation of the semiconductor substrate 100 shown in FIG. 1A at various intermediate stages, in accordance with some embodiments of the disclosure. The semiconductor structure 100 includes a semiconductor substrate 102, a device layer 104 formed on the semiconductor substrate 102, as shown in FIG. 3A, in accordance with some embodiments.

The semiconductor substrate 102 are defined as a plurality of die regions 124 and a scribe line region 126 (including testline regions 128 and monitor cross regions 130, in accordance with some embodiments. The semiconductor structure 100 will be singulated into multiple semiconductor dies which are designed for mobile applications, and may be logic dies (e.g., including central processing unit (CPU), graphics processing units (GPU), system-on-a-chips (SoC), application processors (AP), microcontroller, etc.), memory dies (e.g., dynamic random access memory (DRAM) dies, static random access memory (SRAM) dies, etc.), power management die (e.g., power management integrated circuit (PMIC) die), a radio frequency (RF) dies, sensor dies, micro-electro-mechanical-system (MEMS) dies, signal processing dies (e.g., digital signal processing (DSP) dies), front-end dies (e.g., analog front-end (AFE) dies), high-performance computing (HPC) dies, artificial intelligence (AI) dies, automotive dies, the like, or combinations thereof.

In some embodiments, the semiconductor substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

The device layer 104 includes transistors TR which are electrically coupled to one other to form integrated circuits, as shown in FIG. 3A, in accordance with some embodiments. However, this is not a limitation of the present disclosure. The device layer 104 may include various passive and active microelectronic devices (not shown), such as resistors, capacitors, inductors, diodes, metal-oxide-semiconductor field effect transistors (MOSFETs), complementary MOS (CMOS) transistors, bipolar junction transistors (BJTs), laterally diffused MOS (LDMOS) transistors, high power MOS transistors, FinFETs, nanostructure transistors (e.g., gate-all around transistors), other types of transistors, and/or any combinations thereof.

In some embodiments where the transistors TR are FinFETs, the transistors TR include fin structures 106 functioning as channels of the transistors TR, metal gates 110 functioning as gate terminals of the transistors TR, and epitaxial source/drain features 108 and metal contact plugs 112 together functioning as source or drain terminals of the transistors TR, as shown in FIG. 3A, in accordance with some embodiments. The fin structures 106 and the metal gates 110 may be the same as the fin structures 106 and the metal gates 110 shown in FIG. 2.

A dielectric layer 114 is formed on the semiconductor substrate 102 to surround microelectronic components of the device layer 104, as shown in FIG. 3A, in accordance with some embodiments. The dielectric layer 114 may include shallow trench isolation (STI) feature (e.g., the isolation structure 107 in FIG. 2), spacer layers, an interlayer dielectric layer (ILD), and/or other suitable dielectric features. The dielectric layer 114 is made of more than one dielectric material such as silicon oxide, silicon nitride and/or silicon oxynitride.

An interconnect structure 116 is formed over the device layer 104 and the dielectric layer 114, as shown in FIG. 3B, in accordance with some embodiments. The interconnect structure 116 is a multi-layered or multi-leveled structure, in accordance with some embodiments. The interconnect structure 116 includes stacked levels of insulating layers, e.g., including, in sequence stacked over the device layer 104, intermetal dielectric layers IMD0-IMD13, top metal insulating layers TMD1-TMD2, and first and second passivation layers PAS1 and PAS2, as shown in FIG. 3B, in accordance with some embodiments.

The interconnect structure 116 further includes conductive features disposed in the respective insulating layers IMD0-IMD13, TMD1-TMD2, PAS1 and PAS2, in accordance with some embodiments. The conductive features include metal lines 120 and vias 122 in the intermetal dielectric layers IMD0-IMD13, the top metal insulating layers TMD1-TMD2, and the first second passivation layer PAS1, and a redistribution layer 138 (including bonding pads 140, probe pads 142 and the monitor structure 132 and 134) in the second passivation layer PAS2, in accordance with some embodiments. The vias 122 connect metal lines 120 in different levels (or different planes), and is connected to the transistors TR in the device layer 104 and to the bonding pads 140 and the probe pads 142 of the redistribution structure, in accordance with some embodiments.

The formation of the interconnect structure 116 includes forming the first-level insulating layer (e.g., the intermetal dielectric layer IMD0) and the conductive features (e.g., vias 122) therein, and then forming the second-level insulating layer (e.g., the intermetal dielectric layer IMD1) and the conductive features (e.g., metal lines 120) therein. The formation of an insulating layer and conductive features is repeated until the first passivation layer PAS1 and the conductive features therein are formed.

In some embodiments, the insulating layers IMD0-IMD13, TMD1-TMD2 and PAS1 may be made of one or more dielectric materials, such as silicon oxide (SiO), silicon nitride (SiN), silicon oxynitride (SiON), silicon carbide (SiC), aluminum oxide (Al₂O₃), a dielectric material with low dielectric constant (low-k) such as SiCOH, SiOCN, SiOC, or a combination thereof. In some embodiments, the dielectric materials may be extremely low-k (ELK) dielectric material with a dielectric constant (k) less than about 3.0, or even less than about 2.5. In some embodiments, ELK dielectric materials include carbon-doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon oxide (SiO₂).

In some embodiments, the dielectric materials are deposited using CVD (such as LPCVD, HARP, and FCVD), ALD, spin-on coating, another suitable method, or a combination thereof. A post-curing process (e.g., UV curing) may be performed on the as-deposited ELK dielectric material to form a porous structure.

In some embodiments, the metal lines 120 and the vias 122 are formed using single damascene and/or dual damascene processes. For example, in a dual damascene process, both a trench and a via hole are formed in an insulating layer, with the via hole underlying and connected to the trench. The conductive material is then deposited to fill the trench and the via hole to form a metal line 120 and a via 122, respectively. In a single damascene process, a via hole is first formed in an insulating layer, followed by filling the via hole with a conductive material to form a via 122. A trench is first formed in an insulating layer, followed by filling the trench with a conductive material to form a metal line 120. The deposition process may be CVD, physical vapor deposition (PVD), e-beam evaporation, ALD, electroplating (ECP), electroless deposition (ELD), or a combination thereof.

In some embodiments, the conductive material for the metal lines 120 and the vias 122 may include a diffusion barrier material such as tantalum (Ta), tantalum nitride (TaN), titanium (Ti), titanium nitride (TiN), cobalt tungsten (CoW), another suitable material, or a combination thereof. In some embodiments, the conductive material for the metal lines 120 and the vias 122 may further include a metal bulk material such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), golden (Au), aluminum (Al), another suitable metal material, or a combination thereof over the diffusion barrier material.

A redistribution layer 138 is formed over the first passivation layer PAS1, in accordance with some embodiments. The redistribution layer 138 includes bonding pads 140 within the die region 124, probe pads 142 with the test line region 128 and the monitor structure 132 and 134 within the monitor cross region 130, the configuration of which are discussed above in FIGS. 1A-1E, in accordance with some embodiments. A wafer acceptance test is performed to determine the acceptance rate of the semiconductor structure 100.

The bonding pads 140 and the probe pads 142 are electrically connected to the transistors TR in the device layer 104 through the conductive features of the interconnect structure 116, in accordance with some embodiments. The metal patterns 144, 146 and 148 of the monitor structures 132 and 134 are electrically isolated from the conductive features of the interconnect structure 116 by the passivation layer PAS1, in accordance with some embodiments.

In some embodiments, the redistribution layer 138 is made of metal material such as copper and/or aluminum. In some other embodiments, the redistribution layer 138 may be made of gold, palladium, cobalt, titanium, nickel, silver, graphene, one or more other suitable metal materials, an alloy thereof, or a combination thereof. The formation of the redistribution layer 138 includes depositing a metal layer on the first passivation layer PAS1 using CVD, PVD, e-beam evaporation, ALD, ECP, ELD, or a combination thereof, and then patterning the metal layer using photolithography and etching processes.

A second passivation layer PAS2 is formed over the redistribution layer 138 and the first passivation layer PAS1, in accordance with some embodiments. In some embodiments, the material and the formation of the second passivation layer PAS2 is the same as or similar to the material and the formation of the first passivation layer PAS1. The second passivation layer PAS2 is patterned using photolithography and etching processes to form an opening which partially exposes the bonding pads 140, in accordance with some embodiments.

A polymer layer PI is conformally formed over the second passivation layer PAS2 using a process such as lamination, coating, (e.g., spin-coating), CVD, or the like, in accordance with some embodiments. In some embodiments, the polymer layer PI is made of polymer materials such as epoxy, polyimide, a polybenzoxazole (PBO), or another suitable polymer material. The polymer layer PI is patterned using photolithography and etching processes to form an opening which corresponds to the opening of the second passivation layer PAS2, in accordance with some embodiments.

Under-bump metallurgy structures (UBM) 150 are formed on the bonding pads 140 to fill the opening, in accordance with some embodiments. In some embodiments, the formation of the under-bump metallurgy structures 150 includes depositing a metal seed layer, forming a patterned mask (not shown) on the metal seed layer, plating a metallic material such as copper into the opening of the patterned mask, removing the patterned mask, and etching the portions of the metal seed layer previously covered by the patterned mask.

In some embodiments, the metal seed layer may include a titanium layer and a copper layer over the titanium layer. The metallic material may be copper, nickel, tantalum, vanadium, chromium, gold, tungsten, an alloy thereof, a multi-layer thereof, or a combination thereof. In some embodiments, the under-bump metallurgy structure 150 is made of non-solder metallic material.

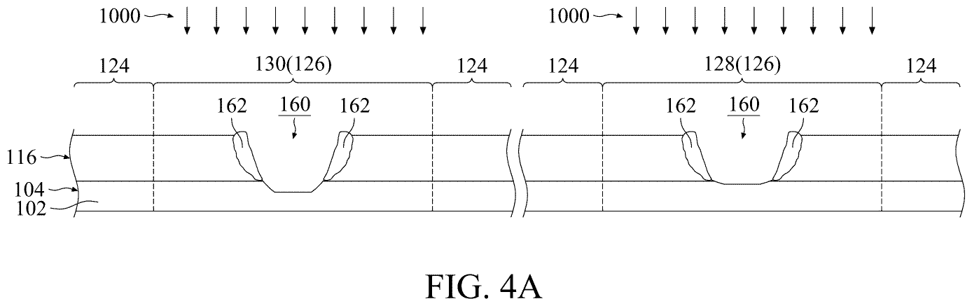

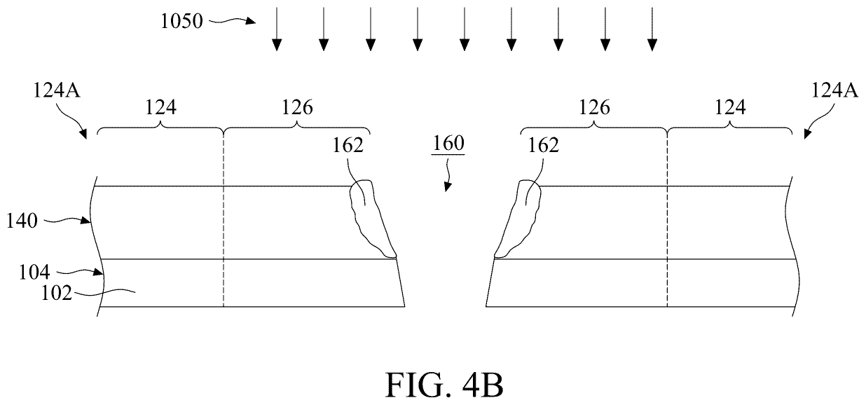

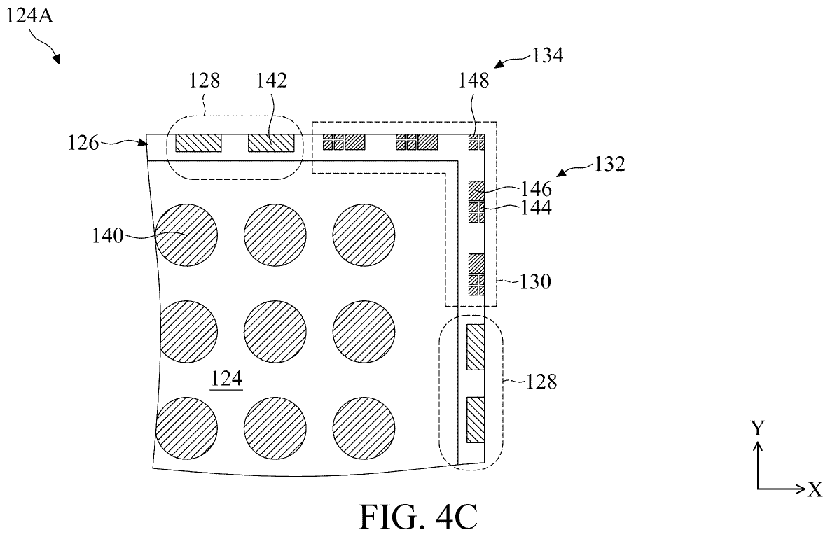

FIGS. 4A and 4B are cross-sectional views illustrating the singulation of dies at various intermediate stages, in accordance with some embodiments of the disclosure. A laser-grooving process 1000 is performed on the semiconductor structure 100 of FIG. 3B to form a groove 160, as shown in FIG. 4A, in accordance with some embodiments. In specific, a laser beam is applied to the semiconductor structure 100 along the streets 126A of the scribe line region 126 and then along the streets 126B of the scribe line region 126 without cutting through the semiconductor structure 100, thereby forming the groove 160, in accordance with some embodiments.

In some embodiments, the groove 160 penetrates through the interconnect structure 116, the device layer 104, and partially into the semiconductor substrate 102. In some embodiments, the laser beam is a UV solid-state laser having a wavelength of about 355 μm, an yttrium-aluminum-garnet (YAG) laser, a neodymium-YAG laser, or other appropriate lasers.

The laser-grooving process 1000 results in recast 162 due to the laser interaction with the interconnect structure 116 and the semiconductor substrate 102, in accordance with some embodiments. In some embodiments, the width of the groove 160 is less than the width of the scribe line region 126, and thus a part of the scribe line region 126 remains. In some other embodiments, the entire scribe line region 126 is removed.

A groove monitor process is performed using visual and/or optical instruments to inspect the dimension (e.g., depth or width) of the groove 160 at the monitor cross regions 130. In the embodiments of the present disclosure, the first-type monitor structures 132 with a relatively low areal density of patterns may suffer heavier laser grooving, and thus may provide a worse condition for inspection of the groove monitor process. Once the dimension of the groove 160 at the position where the first-type monitor structures 132 are disposed meets the specification, it may be determined that the dimension of the groove 160 at other locations also meets the specification. Therefore, semiconductor wafers that do not meet specifications may be scrapped or reworked before shipping, and thus the manufacturing yield of the semiconductor structure may be improved.

In addition, because the crossroads 126C of the scribe line region 126 are being laser grooved twice, the second-type monitor structure 134 may prevent the laser grooving at the crossroads 126C from being too heavy and causing the delamination issue, and at the same time prevent the laser groove from being too light to meet the dimension specification.

A mechanical dicing process 1050 is performed through the groove 160 to cut through the semiconductor substrate 102, as shown in FIG. 4B, in accordance with some embodiments. In some embodiments, the mechanical dicing process includes a mechanical blade dicing step using a diamond embedded blade (not shown) to cut through the semiconductor structure 100 along the scribe line region 126. As a result, the semiconductor structure (or wafer) 100 is singulated or separated into a plurality of semiconductor dies 124A, in accordance with some embodiments. In some embodiments, each of the semiconductor dies 124A includes the die region 124 and partial of the scribe line region 126. In some embodiments, each of the semiconductor dies 124A does not have the scribe line region 126.

FIG. 4C illustrates a top view of a semiconductor die 124A, in accordance with some embodiments of the present disclosure. In some embodiments, an individual semiconductor die 124A includes a die region 124 and a remaining scribe line region 126. The first-type monitor structures 132, the second-type monitor structure 134 and the probe pads 142 may remain within the scribe line region 126 of the semiconductor die 124A, in accordance with some embodiments. The configuration of the first-type monitor structures 132, the second-type monitor structure 134 and the probe pads 142 within the scribe line region 126 of the semiconductor die 124A are similar to that described above in FIGS. 1A-1E, except that part of these components are removed.

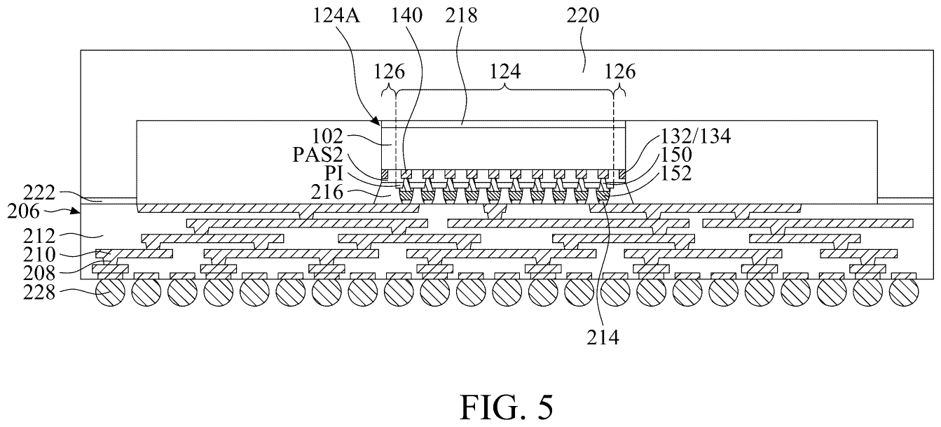

FIG. 5 is a cross-sectional view of a package structure including a semiconductor die 124A shown in FIGS. 4B and 4C, in accordance with some embodiments of the disclosure. A semiconductor die 124A is disposed on the upper surface of a redistribution structure 206, as shown in FIG. 5, in accordance with some embodiments. The semiconductor die 124A is bonded to the under-bump metallurgy structures 214 on the redistribution structure 206 through the bonding elements 152, for example, using flip-chip bonding, and a thermal reflow operation is carried out, in accordance with some embodiments.

In some embodiments, the bonding elements 150 are a controlled collapse chip connection (C4) bump, a solder joint, a microbump, a solder bump, a solder ball, a ball grid array (BGA) ball, another suitable bonding element, or a combination thereof. In some embodiments, the bonding elements 150 are a tin-containing solder bump or solder ball. The tin-containing solder bump or ball may include copper, silver, gold, aluminum, lead, one or more other suitable materials, or a combination thereof. In some embodiments, the bonding elements 150 are lead-free.

The redistribution structure 206 is configured for routing, which enables the formation of a package structure with fan-out features. In some embodiments, the redistribution structure 206 may be referred to as an interposer substrate. In some embodiments, the redistribution structure 206 includes an isolation structure 212 including multiple insulating layers and multiple conductive features 208 and 210 in the insulating layers.

In some embodiments, the conductive features 208 are vias configured to provide vertical electrical routing. In some embodiments, the conductive features 210 include conductive pads, conductive lines and/or conductive traces configured to provide5 horizontal electrical routing. In some embodiments, the insulating layers of the isolation structure 212 may be made of one or more polymer materials. The polymer materials may include polybenzoxazole (PBO), benzocyclobutene (BCB), polyimide (PI), epoxy-based resin, one or more other suitable polymer materials, or a combination thereof. In some embodiments, the polymer material is photosensitive. In alternative embodiments, the insulating layers 212 are made of one or more dielectric materials such as silicon oxide, silicon nitride and/or silicon oxynitride.

In some embodiments, the conductive features 208 and 210 are made of metallic material such as copper, aluminum, gold, palladium, cobalt, titanium, nickel, silver, graphene, one or more other suitable conductive materials, an alloy thereof, or a combination thereof. In some embodiments, the conductive features 208 and 210 are made of non-solder metallic material. In some embodiments, the conductive features 208 and 210 include multiple sub-layers. For example, each of the conductive features 208 and 210 contains multiple sub-layers including Ti/Cu, Ti/Ni/Cu, Ti/Cu/Ti, Al/Ti/Ni/Ag, other suitable sub-layers, or a combination thereof.

Under-bump metallurgy structures 214 are formed over the upper surface of the redistribution structure 206, in accordance with some embodiments. In some embodiments, the under-bump metallurgy structures 214 are used to hold or receive one or more bonding elements such as solder balls. The material and the formation of the under-bump metallurgy structures 214 may be similar to the material and the formation described above.

In some embodiments, the integrated circuits in the device layer 104 (FIG. 3B) of the semiconductor die 124A are electrically coupled to the conductive features 208 and 210 of the redistribution structure 206, in accordance with some embodiments. Although FIG. 5 illustrates that one semiconductor die 124A is on the redistribution structure 206, the presented disclosure may include more than one semiconductor die on the redistribution structure 206.

An underfill material 216 is formed over the upper surface of the redistribution structure 206, thereby encapsulating the bonding elements 152, as shown in FIG. 5, in accordance with some embodiments. The underfill material 216 fills the space between the semiconductor die 124A and the redistribution structure 206, and the space between the bonding elements 152, in accordance with some embodiments. In some embodiments, the underfill material 216 is an electrically insulated adhesive for protecting the bonding elements 152 and/or securing the semiconductor die 124A. In some embodiments, the underfill material 216 is made of epoxy, resin, epoxy molding compounds, another suitable underfill material, or a combination thereof.

A lid or heat spreader 220 is attached to the backside of the semiconductor die 124A through a thermal interface material (TIM) 218, and attached to the upper surface of the redistribution structure 206 through the film 222, as shown in FIG. 5, in accordance with some embodiments. In some embodiments, the lid or heat spreader 220 may be made of a conductive material with a relatively high thermal conductivity, e.g., copper, diamond, boron arsenide, silver, silicon, or the like.

In some embodiments, the thermal interface material 218 is configured to ensure good contact between the surfaces of the lid or heat spreader 220 and the substrate 102 of the semiconductor die 124A. The thermal interface material 218 with good thermal conductivity helps to dissipate heat from the semiconductor die 124A to the lid or heat spreader 220. The thermal interface material 218 may include a polymer, resin, or epoxy as a base material, as well as a filler to improve its thermal conductivity. The filler may include a dielectric filler such as alumina, magnesia, aluminum nitride, boron nitride, and diamond powder. In some embodiments, the film 222 may be thermal interface material, or a solder paste.

Bonding elements 228 are disposed on the backside of the redistribution structure 206, as shown in FIG. 2D, in accordance with some embodiments. In some embodiments, the bonding elements 228 are solder joints, solder balls, ball grid array (BGA) balls, controlled collapse chip connection (C4) bumps, another suitable bonding element, or a combination thereof. In some embodiments, the bonding elements 228 are tin-containing solder balls bumps or solder balls. The tin-containing solder bumps or balls may include copper, silver, gold, aluminum, lead, one or more other suitable materials, or a combination thereof. In some embodiments, the bonding elements 228 are lead-free.

The package structure of FIG. 5 may be further disposed over and bonded to a wiring substrate (not shown) using the bonding elements 228, in accordance with some embodiments. In some embodiments, the wiring substrate is a printed circuit board (PCB). In alternative embodiments, the wiring substrate is an interposer substrate that may then be bonded to another substrate.

As described above, the embodiments of the present disclosure provide the semiconductor structure 100 which includes a test probe pad 130 and a first-type monitor structure 132 within a scribe line region 126. The first-type monitor structure 132 with a plurality of small metal patterns 144 has a lower areal density of patterns than that of the probe pad 130, and thus may suffer heavier laser grooving during a laser-grooving process. As a result, by inspecting the dimension of the groove 160 where the first-type monitor structures 132 are disposed, it may be determined that the dimension of the groove 160 at other locations also meets the specification. Therefore, semiconductor wafers that do not meet specifications may be scrapped or reworked before shipping, and thus the manufacturing yield of the semiconductor structure may be improved.

Embodiments of a semiconductor structure may be provided. The semiconductor wafers may include a monitor structure, which is disposed within a monitor cross region of a scribe line region and includes of a plurality of small metal patterns arranged in an array. After a laser-groove process, it can be determined that the entire groove meets the dimension specification by inspecting the groove at the position where the monitor structure is disposed. Therefore, the manufacturing yield of the semiconductor structure may be improved.

In some embodiments, a semiconductor structure is provided. The semiconductor structure includes a device layer on a substrate, and an interconnect structure over the device layer and including a redistribution layer. The substrate is defined as a die region and a scribe line region, the redistribution layer includes a first probe pad and a first first-type monitor structure within the scribe line region, the first first-type monitor structure includes a plurality of first metal patterns, and a width of one of the first metal patterns is less than a width of the first probe pad, and a length of the one of the first metal patterns is less than a length the first probe pad.

In some embodiments, a semiconductor structure is provided. The semiconductor structure includes a die region, a scribe line region surrounding the die region and including a first street immediate adjacent to a side of the die region, and a monitor structure located within the first street of the scribe line region. The monitor structure includes a plurality of first-type metal patterns laterally spaced apart from each other and arranged in an array, and a second-type metal pattern laterally spaced apart from the plurality of first metal patterns. A dimension of the second-type metal pattern is greater than a dimension of a first metal pattern in the first-type metal patterns.

In some embodiments, a semiconductor structure is provided. The semiconductor structure includes a semiconductor substrate including a die region and a scribe line region surrounding the die region, a device layer on the semiconductor substrate, and a redistribution layer over the device layer. The redistribution layer includes a probe pad and a first monitor structure within the scribe line region, the first monitor structure includes a first plurality of metal patterns, the probe pad is electrically connected to the device layer, and the first plurality of metal patterns is electrically isolated from the device layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a device layer on a substrate; and
an interconnect structure over the device layer and including a redistribution layer, wherein:
the substrate is defined as a die region and a scribe line region,
the redistribution layer includes a first probe pad and a first first-type monitor structure within the scribe line region,
the first first-type monitor structure includes a plurality of first metal patterns, and
a width of one of the first metal patterns is less than a width the first probe pad and a length of the one of the first metal patterns is less than a length of the first probe pad.

2. The semiconductor structure as claimed in claim 1, wherein:
the first first-type monitor structure further includes a second metal pattern immediately adjacent to the plurality of first metal patterns, and
the width of the one of the first metal patterns is less than a width of the second metal pattern, and the length of the one of the first metal patterns is less than a length of the second metal pattern.

3. The semiconductor structure as claimed in claim 2, wherein a spacing between the first probe pad and the first first-type monitor structure is greater than a spacing between the second metal pattern and the plurality of first metal patterns.

4. The semiconductor structure as claimed in claim 1, wherein:
the scribe line region further includes a first street and a second street intersecting the first street at a crossroad,
the first probe pad and the first first-type monitor structure are located within the first street;
the redistribution layer further includes a second-type monitor structure within the crossroad, and
the second-type monitor structure includes a plurality of second metal patterns.

5. The semiconductor structure as claimed in claim 4, wherein the first first-type monitor structure is located between the first probe pad and the second-type monitor structure.

6. The semiconductor structure as claimed in claim 4, wherein in a plan view, a ratio of a sum of areas of the second metal patterns to an area of the second-type monitor structure is greater than about 0.5 and less than about 0.9.

7. The semiconductor structure as claimed in claim 4, wherein:
the redistribution layer further includes a second probe pad and a second first-type monitor structure within the second street of the scribe line region,
the second first-type monitor structure includes a plurality of third metal patterns,
a width of one of the third metal patterns is less than a width of the second probe pad and a length of one of the third metal patterns is less than a length of the second probe pad, and
the second first-type monitor structure is located between the second probe pad and the second-type monitor structure.

8. The semiconductor structure as claimed in claim 1, wherein a spacing between the first metal patterns is less than the width of the one of the first metal patterns.

9. The semiconductor structure as claimed in claim 1, wherein the probe pad is electrically connected to the device layer, and the first metal patterns of the first first-type monitor structure are electrically isolated from the device layer.

10. A semiconductor structure, comprising:
a die region;
a scribe line region surrounding the die region and including a first street immediately adjacent to a side of the die region; and
a monitor structure located within the first street of the scribe line region, wherein the monitor structure includes:
a plurality of first-type metal patterns laterally spaced apart from each other and arranged in an array; and
a second-type metal pattern laterally spaced apart from the plurality of first-type metal patterns, wherein a dimension of the second-type metal pattern is greater than a dimension of a first metal pattern in the plurality of first-type metal patterns.

11. The semiconductor structure as claimed in claim 10, wherein a spacing between the plurality of first-type metal patterns and the second-type metal pattern is less than the dimension of the first metal pattern.

12. The semiconductor structure as claimed in claim 10, wherein the first-type metal patterns are arranged in a 2×4 array.

13. The semiconductor structure as claimed in claim 10, further comprising:
a probe pad arranged within the first street of the scribe line region and immediately adjacent to the monitor structure, wherein the dimension of the probe pad is greater than the dimension of the first metal pattern.

14. The semiconductor structure as claimed in claim 13, wherein:
the plurality of first-type metal patterns includes the first metal pattern, a second metal pattern, a third metal pattern and a fourth metal pattern sequentially arranged,
a sidewall of the first metal pattern is substantially aligned with a first sidewall of the second-type metal pattern, and
a sidewall of the fourth metal pattern is substantially aligned with a second sidewall of the second-type metal pattern opposite the first sidewall of the second-type metal pattern.

15. The semiconductor structure as claimed in claim 10, wherein the monitor structure is made of copper or aluminum.

16. A semiconductor structure, comprising:
a semiconductor substrate including a die region and a scribe line region surrounding the die region;
a device layer on the semiconductor substrate; and
a redistribution layer over the device layer, wherein:
the redistribution layer includes a probe pad and a first monitor structure within the scribe line region,
the first monitor structure includes a first plurality of metal patterns,
the probe pad is electrically connected to the device layer, and
the first plurality of metal patterns is electrically isolated from the device layer.

17. The semiconductor structure as claimed in claim 16, wherein the first plurality of metal patterns includes a small metal pattern and a large metal pattern, a width of the small metal pattern is less than a width of the large metal pattern, and a length of the small metal pattern is less than a length of the large metal pattern.

18. The semiconductor structure as claimed in claim 17, wherein a width of the probe pad is less than the width of the large metal pattern.

19. The semiconductor structure as claimed in claim 16, wherein:
the redistribution layer further includes a second monitor structure within the scribe line region,
the second monitor structure includes a second plurality of metal patterns,
the first plurality of metal patterns in the first monitor structure has a first areal density, and
the second plurality of metal patterns in the second monitor structure has a second areal density that is less than the first areal density.

20. The semiconductor structure as claimed in claim 16, wherein the redistribution layer further includes a bond pad within the die region, and the semiconductor structure further comprises:
an under-bump metallurgy structure on the bond pad.
